(19) United States
(12) Patent Application Publication
(10) Pub. No.: US 2013/0255535 A1
(43) Pub. Date: Oct. 3, 2013

(54) CZTSe NANOINK COMPOSITION AND SPUTTERING TARGET THEREOF

(71) Applicants: Chi-Jie Wang, (US); Shih-Chang Shei, Tainan City (TW); Cheng-Chou Chien, Taipei (TW)

(72) Inventors: Chi-Jie Wang, Tainan City (TW); Shih-Chang Shei, Tainan City (TW)

(21) Appl. No.: 13/853,845

(22) Filed: Mar. 29, 2013

Related U.S. Application Data
(63) Continuation-in-part of application No. 13/193,928, filed on Jul. 29, 2011.

(51) Int. Cl. C23C 14/06; C09D 11/00

(52) U.S. Cl. CPC C23C 14/0629; C09D 11/00
USPC 106/31.13; 204/298.13

(57) ABSTRACT

The present invention provides a Cu₂ZnSnSe₄ (CZTSe) nanoink composition and a CZTSe sputtering target thereof for use in manufacturing an absorption layer of a thin-film solar cell. The CZTSe sputtering target includes a binary multiphase mixture and/or a ternary multiphase mixture. The CZTSe nanoink composition not only includes the binary multiphase mixture and/or ternary multiphase mixture but also includes a chelating agent. Any two of Cu, Zn, Sn, and Se are combined by the chelating agent to form the binary multiphase mixture. Alternatively, any three of Cu, Zn, Sn, and Se are combined by the chelating agent to form the ternary multiphase mixture. By manufacturing the absorption layer of the thin-film solar cell in the aforesaid manner, the absorption layer has a perfect quaternary monophase structure but does not manifest any impure phase detrimental to photoelectric conversion efficiency.

### CROSS-REFERENCE TO RELATED APPLICATION

This application a continuation-in-part application of U.S. patent application Ser. No. 13/193,928 filed on Jul. 29, 2011 and entitled “NANOINK FOR FORMING ABSORBER LAYER OF THIN FILM SOLAR CELL AND METHOD OF PRODUCING THE SAME”, which is hereby incorporated by reference.

### BACKGROUND OF THE INVENTION

1. Technical Field

The present invention relates to copper zinc tin selenide (Cu₂ZnSnSe₄, CZTSe) nanoink compositions and sputtering targets thereof, and more particularly, to a CZTSe nanoink composition and a sputtering target thereof for use in manufacturing an absorption layer of a thin-film solar cell.

2. Description of Related Art

Solar cells are sorts of photovoltaic devices converting sunlight to useable electrical power. Because of improvement in conversion efficiency of the solar cells and reduction of costs for manufacturing products in commercial scale, the interest in solar cells, has obviously expended in recent years. The most common material applied into the solar cells is silicon, which is in form of a single or polycrystalline thick wafer. However, although the silicon-based solar cells hold the high conversion efficiency at over 20%, a significant level of thickness to absorb the sunlight has been retained so that the decrease of manufacturing cost and the expanse of application on irregular surface are restricted.

Another type of solar cells, namely the “thin-film”, distinguished from the silicon-based solar cells has been developing rapidly due to the lower material cost and the competitive conversion efficiency. The typical structure of a thin-film solar cell essentially includes a substrate, a back contact layer, a p-type semiconductor absorber layer, an n-type junction buffer layer, and a transparent layer. Presently, one of most potential absorber layers applied in thin-film solar cells uses a CZTSe compound. Comparing to other absorber layer compounds, the CZTSe compound is suitable for manufacturing the absorber layers of the thin-film solar cells because it has rich zinc and tin and the band gap of selenium compound is between 0.9 eV and 1.7 eV.

For producing a CZTSe absorber layer, one of the conventional techniques was co-evaporation of copper, zinc, tin, and selenide onto a heated substrate in a vacuum, thereby to produce a high-quality CZTSe layer for solar cell fabrication. Another technique is a two-stage process that after formation of copper, zinc, and tin films on a substrate by means of sputtering or vapor deposition selenization method under Se or H₂Se is reacted with the precursor at elevated temperature. Among them, although the vacuum deposition has an advantage of making a high-efficient absorption layer, it shows low materials utilization when making a large-sized absorption layer and also needs expensive equipment. Besides, hydrogen selenide is the most commonly used selenium bearing gas, which is extremely toxic to humans and requires great care in its use.

FIG. 1 is a diagram of X-ray diffraction (XRD) analysis of a conventional Cu₂ZnSnSe₄ (CZTSe) sputtering target. FIG. 2 is a diagram of XRD analysis of a CZTSe thin-film manufactured by a conventional CZTSe sputtering target. The XRD analysis diagrams are drawn with a powder X-ray diffraction instrument (Karaltay DX-2700). A conventional process of manufacturing an absorption layer by sputtering requires the alternate use of multiple elemental targets, binary targets, and ternary targets in manufacturing a thin-film absorption layer beforehand. However, performing sputtering in separate instances not only leads to uneven thickness of the thin-film thus manufactured, but also causes inconsistency in crystalline states and proportions of constituents within the regions of the absorption layer. In attempt to overcome the aforesaid drawbacks, the prior art discloses manufacturing an absorption layer by means of a CZTSe quaternary target. Nonetheless, as revealed in FIG. 1, a conventional CZTSe sputtering target always has a perfect quaternary monophase structure. Referring to FIG. 2, upon completion of sputtering and selenization, a CZTSe thin-film not only contains the Cu₂ZnSnSe₄ compound, but also manifests at least an impure phase that involves copper selenide (CuSe) and copper (IV) selenide (CuSe₂). The impure phase is uncontrollable. The CZTSe thin-film, which manifests the impure phase, deteriorates the efficiency of photoelectric conversion of solar cells.

FIG. 3 shows a FE-SEM image of a CZTSe thin-film manufactured by a conventional CZTSe sputtering target. The FE-SEM image is taken with a Field Emission Scanning Electron Microscopy (FE-SEM; JEOL FE-SEM 7000F.) As revealed by the FE-SEM image shown in FIG. 3, upon completion of selenization, the particles in the CZTSe thin-film not only vary in size, but also fail to form a perfect quaternary monophase structure. As a result, the prior art has hitherto failed to form a CZTSe thin-film absorption layer with a Cu₂ZnSnSe₄ quaternary monophase structure only on a substrate effectively.

### SUMMARY OF THE INVENTION

The present invention relates to a Cu₂ZnSnSe₄ (CZTSe) nanoink composition and a CZTSe sputtering target thereof for use in manufacturing an absorption layer of a thin-film solar cell. Both the CZTSe nanoink composition and the CZTSe sputtering target comprise a binary multiphase mixture and/or a ternary multiphase mixture, but do not comprise a quaternary monophase mixture, such that the absorption layer thus manufactured only has a quaternary monophase structure but does not manifest any other impure phase detrimental to photoelectric conversion efficiency.

The present invention provides a Cu₂ZnSnSe₄ (CZTSe) nanoink composition for use in manufacturing an absorption layer of a thin-film solar cell, the CZTSe nanoink composition comprising: a chelating agent comprising a polyetheramine selected from the group consisting of a monoamine, a diamine, and a triamine; and a binary multiphase mixture formed by combining any two elements of copper, zinc, tin, and selenium via the chelating agent.

The present invention also provides a Cu₂ZnSnSe₄ (CZTSe) nanoink composition for use in manufacturing an absorption layer of a thin-film solar cell, the CZTSe nanoink composition comprising: a chelating agent comprising a polyetheramine selected from the group consisting of a monoamine, a diamine, and a triamine; and a ternary multiphase mixture of any three elements selected from the group consisting of copper, zinc, tin, and selenium and combined via the chelating agent.

The present invention further provides a Cu₂ZnSnSe₄ (CZTSe) sputtering target for use in manufacturing an absorption layer of a thin-film solar cell, the CZTSe sputtering target comprising a binary multiphase mixture of any two elements selected from the group consisting of copper, zinc, tin, and selenium.

The present invention still further provides a Cu₂ZnSnSe₄ (CZTSe) sputtering target for use in manufacturing an absorption layer of a thin-film solar cell, the CZTSe sputtering target comprising a ternary multiphase mixture of any three elements selected from the group consisting of copper, zinc, tin, and selenium.

Implementation of the present invention at least involves the following inventive steps:

1. when manufactured from a CZTSe nanoink composition, an absorption layer of a thin-film solar cell can have a quaternary monophase structure but does not manifest any other impure phase, thereby enhancing the efficiency of photoelectric conversion of the thin-film solar cell;

2. when manufactured by a CZTSe sputtering target, an absorption layer of a thin-film solar cell can have a quaternary monophase structure but does not manifest any other impure phase, thereby enhancing the efficiency of photoelectric conversion of the thin-film solar cell; and

3. a chelating agent comprising p-phenylenediamine speeds up a reaction of synthesis of the CZTSe nanoink composition and shortens response time.

Detailed features and advantages of the present invention are described in detail in the embodiments to allow persons skilled in the art to understand the technical contents of the present invention and implement the present invention accordingly. Persons skilled in the art can readily understand related objectives and advantages of the present invention according to the disclosure in this specification, the claims, and the drawings.

### BRIEF DESCRIPTION OF THE DRAWINGS

FIG. 1 is a diagram of X-ray diffraction (XRD) analysis of a conventional Cu₂ZnSnSe₄ (CZTSe) sputtering target;

FIG. 2 is a diagram of XRD analysis of a CZTSe thin-film manufactured by a conventional CZTSe sputtering target;

FIG. 3 shows a FE-SEM image of a CZTSe thin-film manufactured by a conventional CZTSe sputtering target;

FIG. 4 shows a structural formula of p-phenylenediamine in an embodiment of the present invention;

FIG. 5 shows a structural formula of 3-dibenzoselenophen-4-yl-phenylamine in an embodiment of the present invention;

FIG. 6 is a flow chart of a method for manufacturing a Cu₂ZnSnSe₄ (CZTSe) nanoink composition according to an embodiment of the present invention;

FIG. 7 is a diagram of XRD analysis of a CZTSe sputtering target according to an embodiment of the present invention;

FIG. 8 is a flow chart of a method for manufacturing a CZTSe sputtering target according to an embodiment of the present invention;

FIG. 9 is a flow chart of a method for preparing a CZTSe nanopowder according to an embodiment of the present invention;

FIG. 10 is a flow chart of a method for manufacturing a CZTSe sputtering target by a CZTSe nanopowder according to an embodiment of the present invention;

FIG. 11 is a diagram of XRD analysis of a CZTSe nanopowder according to an embodiment of the present invention;

FIG. 12 is a diagram of XRD analysis of a CZTSe sputtering target according to an embodiment of the present invention;

FIG. 13 is a flow chart of a method for manufacturing an absorption layer of a thin-film solar cell by a CZTSe sputtering target according to an embodiment of the present invention;

FIG. 14 is a flow chart of a method for manufacturing an absorption layer of a thin-film solar cell by a CZTSe nanoink composition according to an embodiment of the present invention;

FIG. 15 is a diagram of XRD analysis of a sintered CZTSe thin-film according to an embodiment of the present invention; and

FIG. 16 shows a FE-SEM image of a sintered CZTSe thin-film according to an embodiment of the present invention.

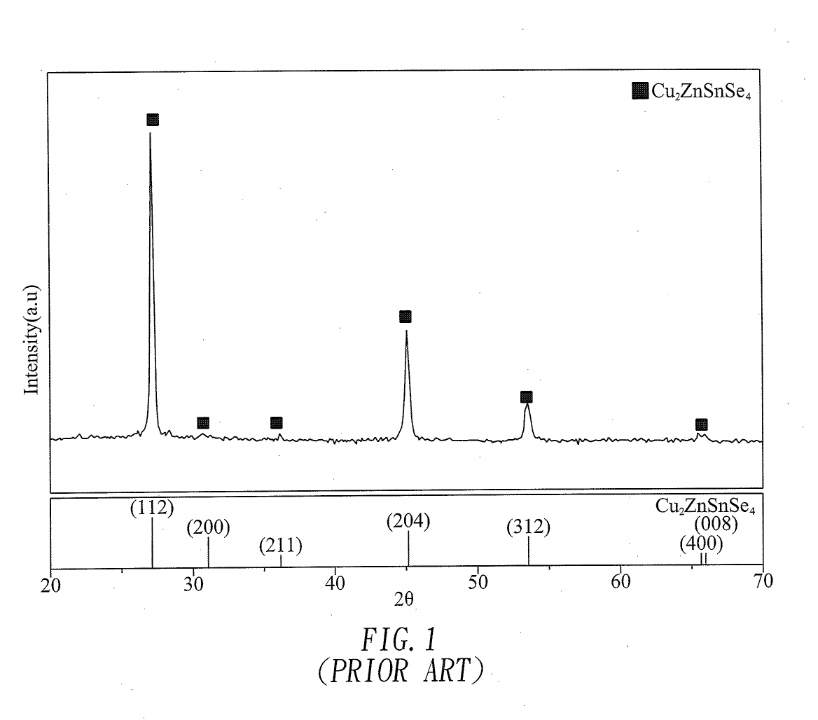

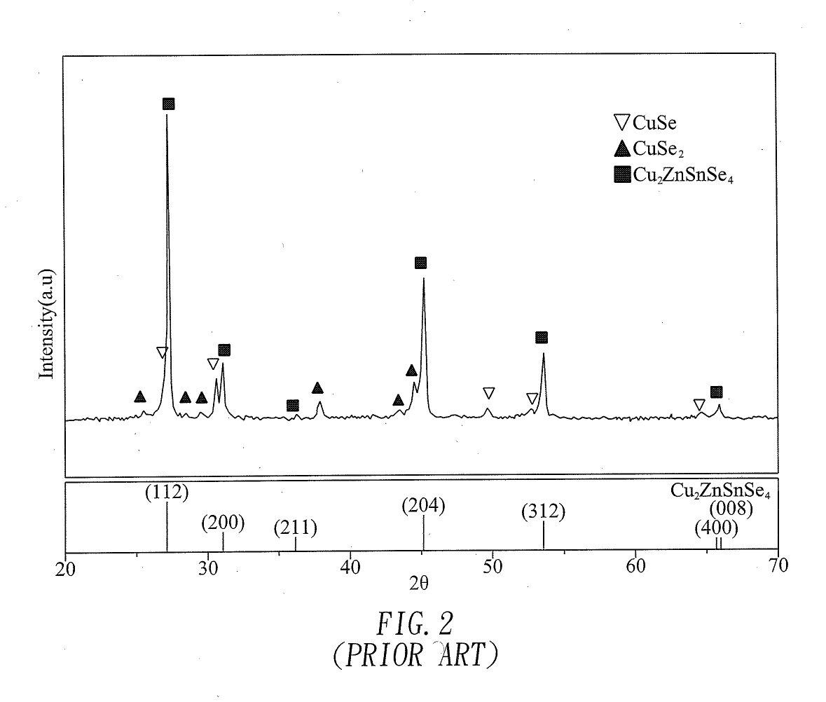

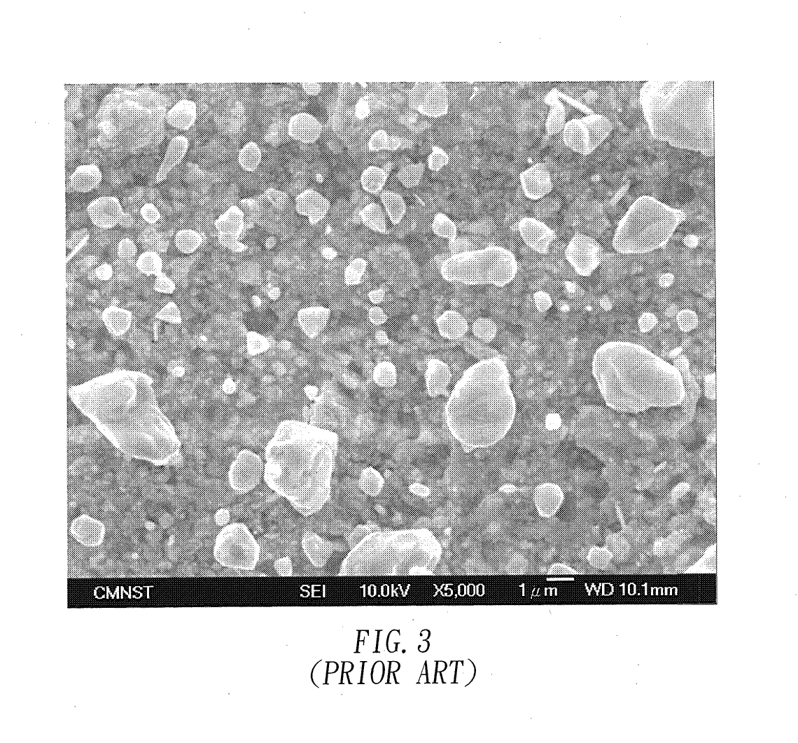

### DETAILED DESCRIPTION OF THE INVENTION

Embodiment of Cu₂ZnSnSe₄ (CZTSe) Nanoink Composition

This embodiment relates to a Cu₂ZnSnSe₄ (CZTSe) nanoink composition for use in manufacturing an absorption layer of a thin-film solar cell. The CZTSe nanoink composition comprises a chelating agent, a binary multiphase mixture, and/or a ternary multiphase mixture. The binary multiphase mixture is formed by combining any two elements selected from copper (Cu), zinc (Zn), tin (Sn), and selenium (Se) by means of the chelating agent, such as CuSe₂, CuSe, SnSe, or ZnSe. The ternary multiphase mixture is also formed by combining any three elements selected from Cu, Zn, Sn, and Se by means of the chelating agent, and includes Cu₂SnSe₃, for example.

Therefore, the CZTSe nanoink composition either comprises a chelating agent and a binary multiphase mixture or comprises a chelating agent and a ternary multiphase mixture. Alternatively, the CZTSe nanoink composition comprises a chelating agent, a binary multiphase mixture, and a ternary multiphase mixture. In each of the aforesaid composition-related scenarios, the CZTSe nanoink composition can further comprise a single element, such as Cu, Zn, Sn, or Se.

The chelating agent comprises a polyetheramine. The polyetheramine is one selected from the group consisting of a monoamine, a diamine, and a triamine. The chelating agent has a boiling point of 200° C. and above, functions as a collision medium required for a reaction, and features a high boiling point, so as to provide the reaction activation energy required for synthesis and thereby enable the chemical reaction to occur and finish. The polyetheramine-containing chelating agent chelates Cu, Zn, Sn, and Se and thereby functions as a binder between Cu, Zn, Sn, and Se. The polyetheramine causes Cu, Zn, Sn, and/or Se to dissociate and dissolve, enables a reaction to be performed thereon, and enables the nanoink composition to be prepared.

The aforesaid monoamine is one selected from the group consisting of alkyl polyalkylene glycol amine, bis(methyl triethylene glycol) amine, butyl triethylene glycol amine, lauryl polypropylene glycol amine, methyl tripropylene glycol amine, phenol polypropylene glycol amine, polypropylene glycol amine, bis(methyl tripropylene glycol) amine, N-methyl methyl propylene glycol amine, methyl polypropylene glycol amine, bis(methyl polypropylene glycol) amine, tris(methyl diglycol) amine, methyl polyalkylene glycol amine with random or blockwise distribution of the ethylene glycol, and propylene glycol. The diamine is one selected from the group consisting of triethylene glycol diamine, tripropylene glycol diamine, polyethylene glycol diamine, polypropylene glycol diamine, polyalkylene glycol diamine with random or blockwise distribution of ethylene glycol and propylene glycol units, butanediol polyalkylene glycol diamine, and resorcinol polyalkylene glycol diamine. The triamine is one selected from the group consisting of glycerol polyalkylene glycol triamine with random or blockwise distribution of the ethylene glycol and propylene glycol unit, bis(triethylene glycol amine) amine, and bis(polyalkylene glycol amine) amine.

In addition to the polyetheramine, the chelating agent further comprises p-phenylenediamine and 3-dibenzoselenophen-4-yl-phenylamine. For instance, polyetheramine accounts for 91-92% of the weight of the chelating agent, p-phenylenediamine accounts for 3-4% of the weight of the chelating agent, and 3-dibenzoselenophen-4-yl-phenylamine accounts for 5% of the weight of the chelating agent.

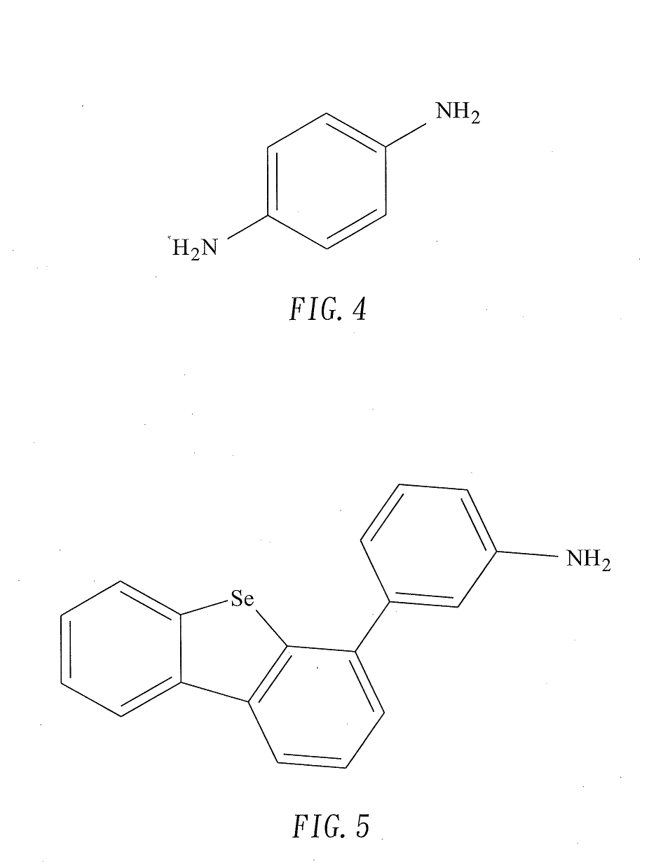

Referring to FIG. 4, since p-phenylenediamine has a symmetric chemical structure, its molecular dipole-moment equals zero, such that p-phenylenediamine functions as a surfactant toward polyetheramine and thereby forms a surfactant-complex; as a result, Cu, Zn, Sn, and Se can come into tight contact with and thus react with polyetheramine. Two amino groups of p-phenylenediamine have a chelating effect and thereby form a chelating complex together with Cu, Zn, Sn, and Se, thus speeding up the chemical reaction and shortening the response time. Referring to FIG. 5, 3-dibenzoselenophen-4-yl-phenylamine behaves in the same manner as polyetheramine and p-phenylenediamine do, that is, having a complex chelating effect, thus speeding up the chemical reaction.

In conclusion, a CZTSe nanoink composition is characterized by: combining Cu, Zn, Sn, and/or Se with a chelating agent, thereby to form a binary multiphase mixture of any two elements selected from the group consisting of Cu, Zn, Sn, and Se and/or form a ternary multiphase mixture of any three elements selected from the group consisting of Cu, Zn, Sn, and Se. In case a trace of Cu, Zn, Sn, and/or Se is not combined, it will be manifested in a unitary form in the CZTSe nanoink composition.

The CZTSe nanoink composition further comprises an alcohol whereby the chelating agent is prevented from condensing. The alcohol is one selected from the group consisting of methanol, ethanol, butanol, and tert-butanol. The chelating agent can also function as a diluting agent for adjusting the concentration of the CZTSe nanoink composition.

Embodiment of Method for Manufacturing Cu₂ZnSnSe₄ (CZTSe) Nanoink Composition

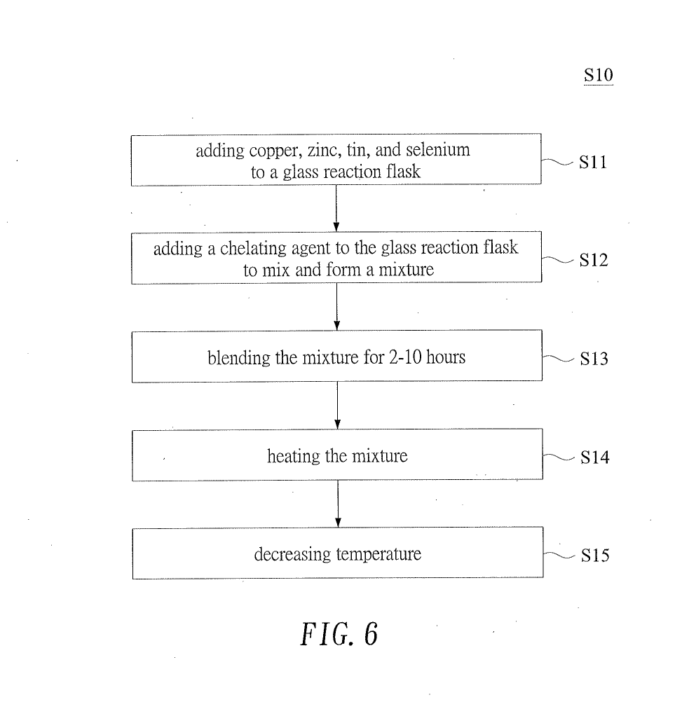

Referring to FIG. 6, this embodiment relates to a method for manufacturing a CZTSe nanoink composition (S10) for use in manufacturing an absorption layer of a thin-film solar cell. The method (S10) for manufacturing the CZTSe nanoink composition comprises the steps of: adding Cu, Zn, Sn, and Se to a glass reaction flask (step S11); adding a chelating agent to the glass reaction flask to mix and form a mixture (step S12); blending the mixture for 2-10 hours (step S13); heating mixture (step S14); and decreasing temperature (step S15).

Adding Cu, Zn, Sn, and Se to a glass reaction flask (step S11): providing a glass reaction flask; positioning a blending stick inside the glass reaction flask; and putting the glass reaction flask above a heater. While the reaction is taking place, add Cu, Zn, Sn, and Se to the glass reaction flask, and introduce an inert gas (such as nitrogen gas, helium gas, or neon gas) to the glass reaction flask at the normal pressure (i.e., 1 atmospheric pressure).

Adding the chelating agent to the glass reaction flask to mix and form a mixture (step S12): after step S11, adding the chelating agent to the glass reaction flask to cause the chelating agent to react with Cu, Zn, Sn, and Se, thereby to mix and form a mixture. The chelating agent either comprises polyetheramine or further comprises p-phenylenediamine and 3-dibenzoselenophen-4-yl-phenylamine. The polyetheramine is one selected from the group consisting of a monoamine, a diamine, and a triamine. The constituents of the chelating agent are described in detail in the description of an embodiment of a CZTSe nanoink composition and thus are not reiterated below.

Blending the mixture for 2-10 hours (step S13): after step S12, blending the mixture for 2-10 hours by means of the blending stick, thereby to mix a chelating agent and Cu, Zn, Sn, and Se thoroughly. The purpose of step S13 is to remove oxygen gas and water vapor from the mixture. Furthermore, the blending process enables and enhances the uniform distribution of Cu, Zn, Sn, and Se in the CZTSe nanoink composition.

Heating the mixture (step S14): heating up the mixture in the glass reaction flask by the heater beneath the glass reaction flask, wherein the heater can control the temperature of the mixture, so as to raise the temperature, maintain the temperature between 230° C. and 250° C., and allow the mixture to undergo the chemical reaction for 2-60 hours. If the chelating agent only comprises polyetheramine, it will be necessary for the mixture to undergo the chemical reaction for 5-60 hours at 230° C.-250° C. If the chelating agent comprises polyetheramine, p-phenylenediamine, and 3-dibenzoselenophen-4-yl-phenylamine, the required duration of the chemical reaction can be shortened to 2-35 hours, because p-phenylenediamine and 3-dibenzoselenophen-4-yl-phenylamine speed up the chemical reaction. By putting required reactants together (that is, adding the chelating agent, Cu, Zn, Sn, and Se to the glass reaction flask) before the heating process begins, it dispenses with the hassles of adding the required reactants in the course of a high-temperature reaction.

Decreasing temperature (step S15): after step S14, decreasing the temperature of the mixture to room temperature (such as 30° C. approximately), thereby to obtain the CZTSe nanoink composition, wherein the CZTSe nanoink composition comprises a chelating agent, and a binary multiphase mixture, and/or a ternary multiphase mixture. As described above in the embodiment of the CZTSe nanoink composition, the binary multiphase mixture consists of any two elements selected from the group consisting of Cu, Zn, Sn, and Se, whereas the ternary multiphase mixture consists of any three elements selected from the group consisting of Cu, Zn, Sn, and Se. By adding a chelating agent, it is feasible to combine Cu, Zn, Sn, and Se, thereby to form a binary multiphase mixture and/or a ternary multiphase mixture.

Furthermore, p-phenylenediamine is as effective in effectuating emulsification and suspension as a surfactant. Hence, the addition of p-phenylenediamine and 3-dibenzoselenophen-4-yl-phenylamine to the chelating agent enhances the viscosity of the CZTSe nanoink composition, enhances the uniform distribution of the nanoparticles of the binary multiphase mixture or ternary multiphase mixture, and reduces the size of the nanoparticles of the binary multiphase mixture or ternary multiphase mixture. Thus, it also can prevent separation of layers and prevent precipitation, thereby rendering it efficient to form the CZTSe thin-film on the substrate by a spray coating technique or a screen printing technique, thereby to form an absorption layer of a thin-film solar cell.

Embodiment of Cu₂ZnSnSe₄ (CZTSe) Sputtering Target

This embodiment relates to a Cu₂ZnSnSe₄ (CZTSe) sputtering target for use in manufacturing an absorption layer of a thin-film solar cell. The CZTSe sputtering target comprises a binary multiphase mixture and/or a ternary multiphase mixture. The binary multiphase mixture consists of any two elements selected from the group consisting of Cu, Zn, Sn, and Se, such as CuSe₂, CuSe, SnSe, and ZnSe. The ternary multiphase mixture consists of any three elements selected from the group consisting of Cu, Zn, Sn, and Se, such as Cu₂SnSe₃.

Therefore, the CZTSe sputtering target comprises either the binary multiphase mixture or the ternary multiphase mixture. Alternatively, the CZTSe sputtering target comprises both the binary multiphase mixture and the ternary multiphase mixture. In each of the aforesaid composition-related scenarios, the CZTSe sputtering target can further comprise a single element, such as Cu, Zn, Sn, or Se. Since the CZTSe sputtering target is manufactured (wherein the method for manufacturing the CZTSe sputtering target is described hereunder later) by removing the chelating agent and then processing the CZTSe nanoink composition. Hence, in this regard, the constituent of the CZTSe sputtering target is similar to the constituent of the CZTSe nanoink composition.

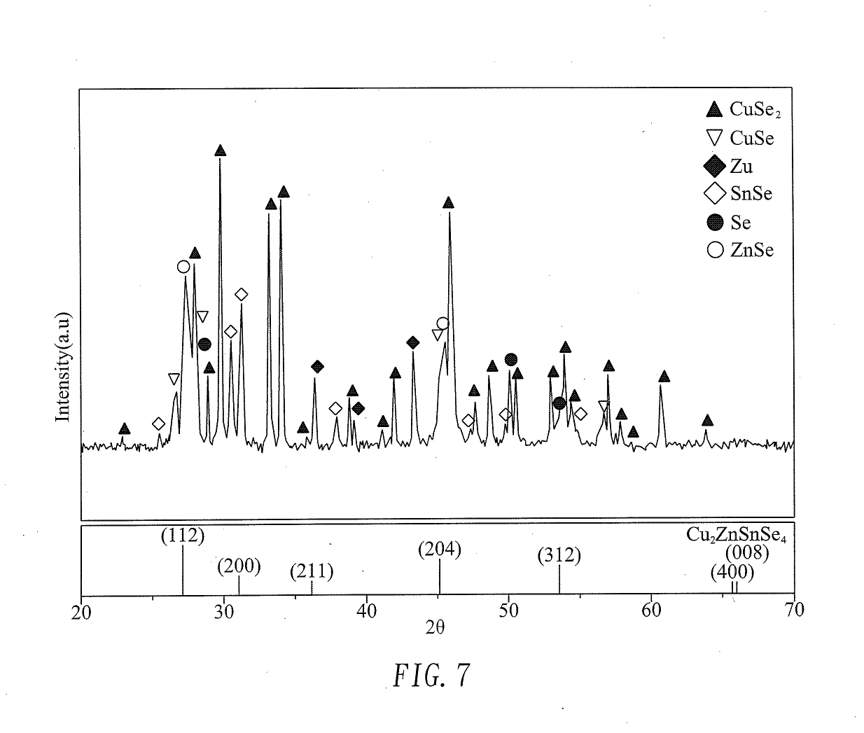

Referring to FIG. 7, there is shown a diagram of XRD analysis of a CZTSe sputtering target according to an embodiment of the present invention. The XRD analysis diagram is drawn with a powder X-ray diffraction instrument (Karaltay DX-2700). As shown in FIG. 7, the CZTSe sputtering target comprises a binary multiphase mixture, including CuSe₂, CuSe, SnSe, and ZnSe, as well as a single element, such as Zn or Se.

Embodiment of Method for Manufacturing Cu₂ZnSnSe₄ (CZTSe) Sputtering Target

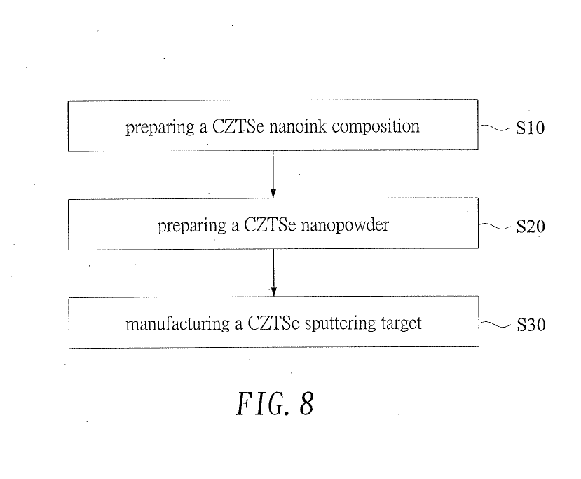

Referring to FIG. 8, this embodiment relates to a method for manufacturing a Cu₂ZnSnSe₄ (CZTSe) sputtering target. The CZTSe sputtering target is for use in manufacturing an absorption layer of a thin-film solar cell. The method for manufacturing the CZTSe sputtering target comprises the steps of: preparing a CZTSe nanoink composition (step S10); preparing a CZTSe nanopowder (step S20); and manufacturing a CZTSe sputtering target (step S30).

Preparing a CZTSe nanoink composition (step S10): referring to FIG. 6, as described above in the description of an embodiment of the method for manufacturing the CZTSe nanoink composition, the process of preparing the CZTSe nanoink composition takes place in the presence of an inert gas and at the normal pressure, and comprises the steps of: adding Cu, Zn, Sn, and Se to a glass reaction flask (step S11); adding a chelating agent to the glass reaction flask to mix and form a mixture (step S12); blending the mixture for 2-10 hours (step S13); heating the mixture (step S14); and decreasing temperature (step S15). The steps are described in detail in the description of an embodiment of a method for manufacturing the CZTSe nanoink composition and thus are not reiterated below.

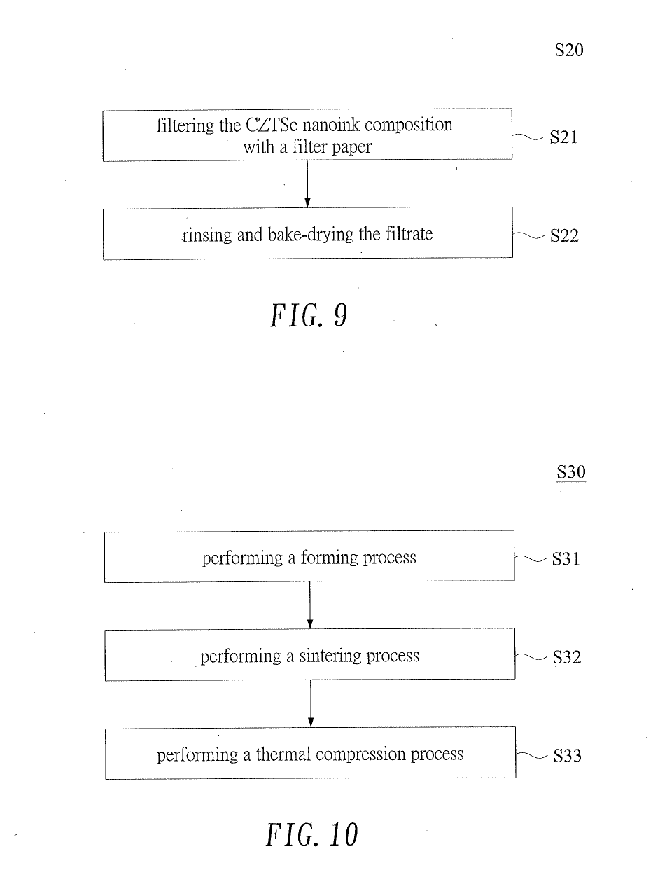

Preparing a CZTSe nanopowder (step S20): referring to FIG. 9, after step S10, filtering the CZTSe nanoink composition with a filter paper (step S21) to produce a filtrate, and then rinsing and bake-drying the filtrate (step S22). The filtrate is rinsed either with ethanol and acetone alternately, or with ethanol, acetone, and toluene alternately, to remove the chelating agent from the filtrate. After the filtering and rinsing process is done, the filtrate is placed in a vacuum baker with a temperature of 60° C. so that the filtrate undergoes drying for 6-12 hours until the CZTSe nanopowder is obtained.

Manufacturing a CZTSe sputtering target (step S30): referring to FIG. 10, performing a forming process (step S31), a sintering process (step S32), and a thermal compression process (step S33) on the CZTSe nanopowder previously prepared in step S20, so as to manufacture the CZTSe sputtering target. Since related techniques of manufacturing a target from an alloy powder by means of forming, sintering, and thermal compression are well known by persons skilled in the art, their details are not reiterated below. The scope of this embodiment is not restricted to the aforesaid techniques of manufacturing a target by means of forming, sintering, and thermal compression. Persons skilled in the art are able to manufacture a CZTSe sputtering target from the CZTSe nanopowder prepared in step S20, using any means of manufacturing a target from an alloy powder.

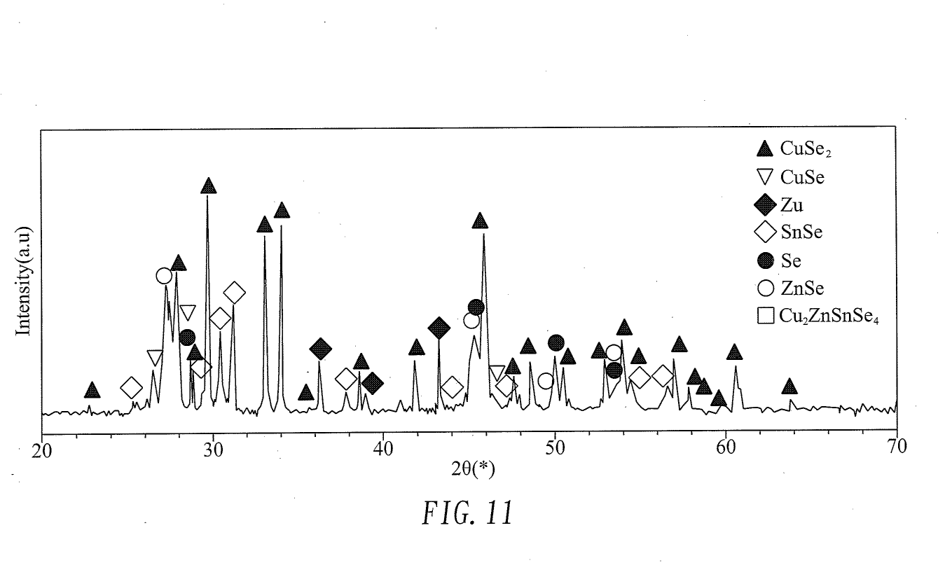

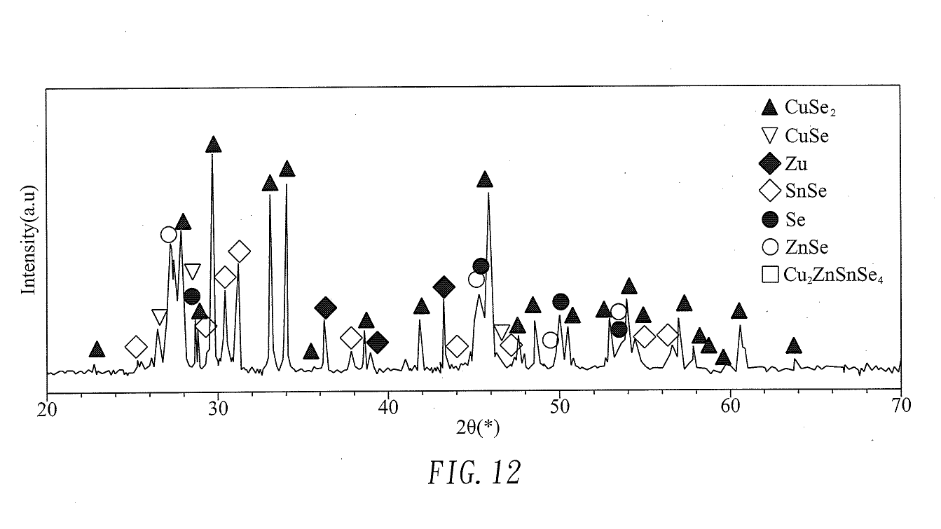

Referring to FIG. 11 and FIG. 12, there are shown diagrams of XRD analysis of a CZTSe nanopowder and a CZTSe sputtering target, respectively. The XRD analysis diagrams are drawn with a powder X-ray diffraction instrument (Karaltay DX-2700). Since no chemical changes occur to the process of manufacturing the CZTSe sputtering target from the CZTSe nanopowder, both the CZTSe nanopowder and the CZTSe sputtering target must have the same constituents and composition, as verified in FIG. 11 and FIG. 12.

The CZTSe nanopowder merely serves to remove the chelating agent from the CZTSe nanoink composition; hence, both the CZTSe nanopowder and the CZTSe sputtering target comprise a binary multiphase mixture and/or a ternary multiphase mixture. The binary multiphase mixture consists of any two elements selected from the group consisting of Cu, Zn, Sn, and Se, such as CuSe₂, CuSe, SnSe, and ZnSe. The ternary multiphase mixture consists of any three elements selected from the group consisting of Cu, Zn, Sn, and Se, such as Cu₂SnSe₃. Hence, the CZTSe sputtering target comprises either the binary multiphase mixture or the ternary multiphase mixture. Alternatively, the CZTSe sputtering target comprises both the binary multiphase mixture and the ternary multiphase mixture. In each of the aforesaid composition-related scenarios, the CZTSe sputtering target can further comprise a single element, such as Cu, Zn, Sn, or Se.

Embodiment of Method for Manufacturing Absorption Layer of Thin-Film Solar Cell

This embodiment relates to a method for manufacturing an absorption layer of a thin-film solar cell. The manufacturing of an absorption layer of a thin-film solar cell can be carried out mainly in two ways: first, sputtering a CZTSe thin-film on a substrate by a sputtering technique and with a CZTSe sputtering target; second, forming a CZTSe thin-film on a substrate by a spray coating technique or a screen printing technique and with a CZTSe nanoink composition. They are described in detail below.

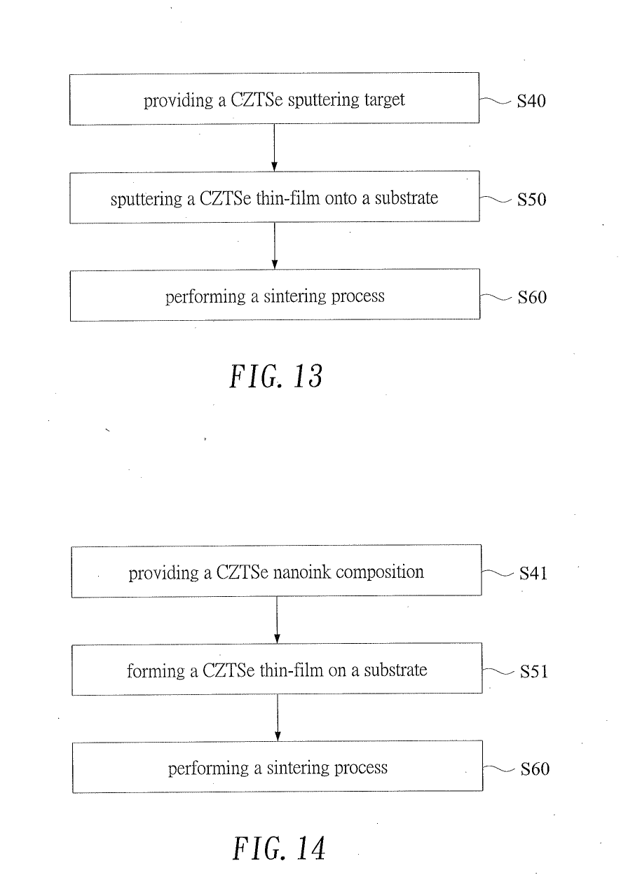

Referring to FIG. 13, a method for manufacturing an absorption layer of a thin-film solar cell by means of a CZTSe sputtering target comprises the steps of: providing a CZTSe sputtering target (step S40); sputtering a CZTSe thin-film onto a substrate (step S50); and performing a sintering process (step S60).

Providing a CZTSe sputtering target (step S40): providing a CZTSe sputtering target that comprises a binary multiphase mixture and/or a ternary multiphase mixture, wherein, in particular, the CZTSe sputtering target required for this embodiment was previously manufactured by the aforesaid method for manufacturing a CZTSe sputtering target. The binary multiphase mixture consists of any two elements selected from the group consisting of Cu, Zn, Sn, and Se, such as CuSe₂, CuSe, SnSe, and ZnSe. The ternary multiphase mixture consists of any three elements selected from the group consisting of Cu, Zn, Sn, and Se, such as Cu₂SnSe₃. In addition to the binary multiphase mixture and/or ternary multiphase mixture, the CZTSe sputtering target further comprises a single element, such as Cu, Zn, Sn, or Se. Related details of the CZTSe sputtering target are described above in the description of the embodiment of the CZTSe sputtering target and thus are not reiterated below. Referring to FIG. 7, the CZTSe sputtering target thus manufactured comprises a binary multiphase mixture, including CuSe₂, CuSe, SnSe, and ZnSe, as well as a single element, Zn or Se.

Sputtering a CZTSe thin-film onto a substrate (step S50): after step S40, using the CZTSe sputtering target as the sputtering target in a vacuum environment to sputter a CZTSe thin-film onto a substrate, wherein the substrate is a molybdenum glass substrate, a metallic substrate, a stainless steel substrate, or any substrate suitable for use in manufacturing thin-film solar cells. The whole process of sputtering a CZTSe thin-film can take place in a vacuum radio-frequency sputtering machine. Since sputtering techniques are well known by persons skilled in the art, they are not described in detail hereunder. The most important essential technical feature of this embodiment is as follows: using a CZTSe sputtering target that only comprises a single element, a binary multiphase mixture, and/or a ternary multiphase mixture to form a CZTSe thin-film on a substrate by a sputtering technique.

Performing a sintering process (step S60): after step S50, a sintering process is performed on the CZTSe thin-film at 500° C.-580° C. and for 30-60 minutes, such that the CZTSe thin-film acquires a quaternary monophase structure, that is, Cu₂ZnSnSe₄.

Referring to FIG. 14, the method for manufacturing an absorption layer of a thin-film solar cell by the CZTSe nanoink composition comprises the steps of: providing a CZTSe nanoink composition (step S41); forming a CZTSe thin-film on a substrate (step S51); and performing a sintering process (step S60).

Providing a CZTSe nanoink composition (step S41): providing the CZTSe nanoink composition that comprises a binary multiphase mixture and/or a ternary multiphase mixture, wherein, in particular, the CZTSe nanoink composition thus provided was previously prepared by the aforesaid method for manufacturing a CZTSe nanoink composition. In addition to a binary multiphase mixture and/or a ternary multiphase mixture, the CZTSe nanoink composition not only comprises a single element, such as Cu, Zn, Sn, or Se, but also comprises a chelating agent. Related details of the CZTSe nanoink composition are described in the above description of an embodiment of a CZTSe nanoink composition and thus are not described again hereunder.

Forming a CZTSe thin-film on a substrate (step S51): after step S41, the CZTSe nanoink composition is applied to a substrate in a non-vacuum environment, wherein the substrate is a molybdenum glass substrate, a metallic substrate, a stainless steel substrate, or any substrate suitable for use in manufacturing thin-film solar cells. The whole process of forming the CZTSe thin-film is carried out in a non-vacuum spray coating machine by a spray coating technique or carried out in a non-vacuum screen printing machine by a screen printing technique.

Performing a sintering (step S60): after step S51, a sintering process is performed on the CZTSe thin-film at 500° C.-580° C. for 30-60 minutes, such that the CZTSe thin-film acquires a quaternary monophase structure, that is, Cu₂ZnSnSe₄.

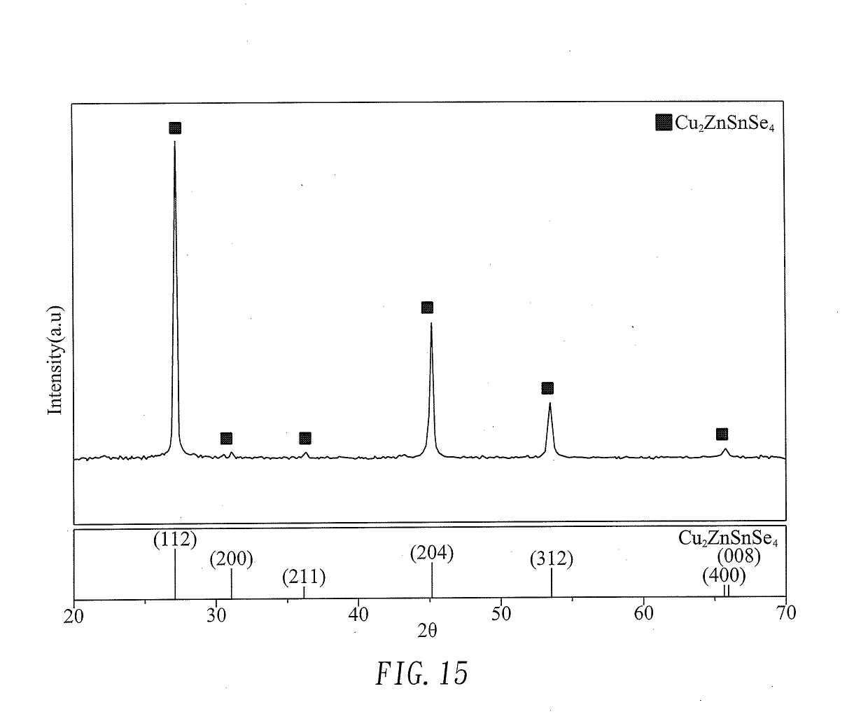

Referring to FIG. 15, there is shown a diagram of XRD analysis of a sintered CZTSe thin-film according to an embodiment of the present invention. The XRD analysis diagram is drawn with a powder X-ray diffraction instrument (Karaltay DX-2700). As indicated by the XRD analysis diagram, the resultant CZTSe thin-film does have a stannite structure of CZTSe, and the sintered CZTSe thin-film no longer manifests an impure phase of a binary multiphase mixture or ternary multiphase mixture but only has a perfect quaternary monophase structure, regardless of whether the CZTSe thin-film is formed by a CZTSe sputtering target or a CZTSe nanoink composition.

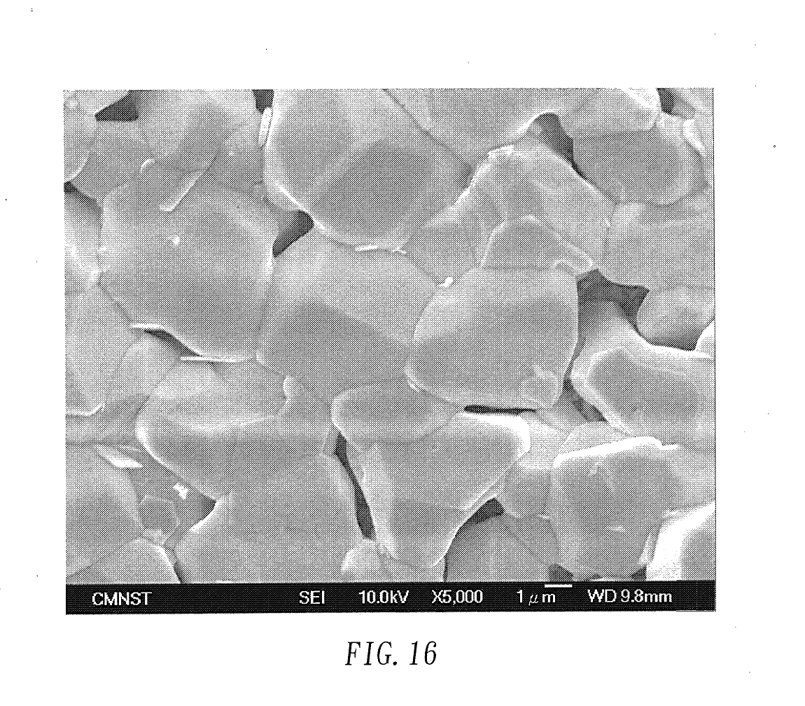

Referring to FIG. 16, there is shown a FE-SEM image of a sintered CZTSe thin-film according to an embodiment of the present invention. The FE-SEM image is taken with a Field Emission Scanning Electron Microscopy (FE-SEM; JEOL FE-SEM 7000F.) As revealed by the FE-SEM image, upon completion of the sintering process, CZTSe particles in the CZTSe absorption layer are enlarged, thereby to form the CZTSe thin-film, and the CZTSe thin-film thus formed functions as the absorption layer capable of absorbing light and characterized by high conductivity.

### Experiment I

Provide a 500 ml glass reaction flask. Put a Teflon blender in the glass reaction flask. Introduce nitrogen gas into the glass reaction flask, and fill the glass reaction flask with the nitrogen gas for 30 minutes. Add 300 grams of polyetheramine (JEFFAMINE® D-400 Polyetheramine, Huntsman) liquid to the glass reaction flask. Then, add 28 grams of a copper powder, 14.2 grams of a zinc powder, 26 grams of a tin powder, and 70 grams of a selenium powder, wherein each of which features a 99.99% purity. Perform blending for 5 hours to remove water vapor and oxygen gas from the mixture in the glass reaction flask. Heat the mixture in the glass reaction flask to 230-250° C. with a heater capable of controlling temperature, such that the chemical reaction occurs to the mixture under the aforesaid condition for 40 hours. Afterward, turn off the heater to allow the temperature to drop spontaneously to room temperature, which is about 30° C., thereby yielding about 438 grams of a black liquid.

The black liquid thus manufactured is the anticipated CZTSe nanoink composition. The CZTSe nanoink composition can be directly applied to the substrate by a spray coating technique or a screen printing technique, and then the absorption layer of a thin-film solar cell is manufactured by a subsequent process.

Alternatively, add 200 ml of 99% ethanol to the CZTSe nanoink composition and blend it for 2 hours approximately. Then, filter the CZTSe nanoink composition with a filter paper (ADVANTEC No. 5A). Afterward, rinse the filtrate with 200 ml of acetone and 200 ml of ethanol. Finally, the filtrate undergoes a drying process in a vacuum baker at 60° C. for 10 hours (and at a vacuum pressure of 0.1 torr approximately), thereby yielding 138 grams of CZTSe nanopowder.

After the CZTSe nanopowder has been prepared, a CZTSe sputtering target is manufactured by performing a forming process, a sintering process, and a thermal compression process. Eventually, with the CZTSe sputtering target, a CZTSe thin-film is formed on a substrate by sputtering and then subjected to a sintering process at 500° C.-580° C. for 30-60 minutes, such that the CZTSe thin-film acquires a quaternary monophase structure, that is, Cu₂ZnSnSe₄.

### Experiment II

Provide a 1000 ml glass reaction flask. Put a Teflon blender in the glass reaction flask. Introduce nitrogen gas into the glass reaction flask, and fill the glass reaction flask with the nitrogen gas for 30 minutes. Add 400 grams of polyetheramine (JEFFAMINE® D-400 Polyetheramine, Huntsman) liquid to the glass reaction flask. Then, add 56 grams of a copper powder, 28.4 grams of a zinc powder, 52 grams of a tin powder, and 140 grams of a selenium powder, wherein each of which features a 99.99% purity. Perform blending for 5 hours to remove water vapor and oxygen gas from the mixture in the glass reaction flask. Heat the mixture in the glass reaction flask to 230-250° C. with a heater capable of controlling temperature, such that the chemical reaction occurs to the mixture under the aforesaid condition for 40 hours. Afterward, turn off the heater to allow the temperature to drop spontaneously to room temperature, which is about 30° C.

A black liquid thus manufactured is the anticipated CZTSe nanoink composition. The CZTSe nanoink composition can be directly applied to the substrate by a spray coating technique or a screen printing technique, and then the absorption layer of a thin-film solar cell is manufactured by a subsequent process.

Then, filter the CZTSe nanoink composition with a filter paper (whatman#4). Afterward, rinse the filtrate with 2000 ml of ethanol, 1000 ml of toluene, and 2000 ml of acetone. Finally, the filtrate undergoes a drying process in a vacuum baker at 60° C. for 10 hours, thereby yielding 276 grams of CZTSe nanopowder.

After the CZTSe nanopowder has been prepared, a CZTSe sputtering target is manufactured by performing a forming process, a sintering process, and a thermal compression process. Eventually, with the CZTSe sputtering target, a CZTSe thin-film is formed on a substrate by sputtering and then subjected to a sintering process at 500° C.-580° C. for 30-60 minutes, such that the CZTSe thin-film acquires a quaternary monophase structure, that is, Cu₂ZnSnSe₄.

### Experiment III

Provide a 2000 ml glass reaction flask. Put a Teflon blender in the glass reaction flask. Introduce nitrogen gas into the glass reaction flask, and fill the glass reaction flask with the nitrogen gas for 30 minutes. Add 690 grams of polyetheramine (JEFFAMINE® D-400 Polyetheramine, Huntsman) liquid, 22.5 grams of a p-phenylenediamine powder, and 37.5 grains of a 3-dibenzoselenophen-4-yl-phenylamine powder to the glass reaction flask. Then, add 180 grams of a copper powder, 91 grams of a zinc powder, 166 grams of a tin powder, and 448 grams of a selenium powder, wherein each of which features a 99.99% purity. Perform blending for 5 hours to remove water vapor and oxygen gas from the mixture in the glass reaction flask. Heat the mixture in the glass reaction flask to 230-250° C. with a heater capable of controlling temperature, such that the chemical reaction occurs to the mixture under the aforesaid condition for 25 hours. Afterward, turn off the heater to allow the temperature to drop spontaneously to room temperature, which is about 30° C.

A black liquid thus manufactured is the anticipated CZTSe nanoink composition. The CZTSe nanoink composition can be directly applied to the substrate by a spray coating technique or a screen printing technique, and then the absorption layer of a thin-film solar cell is manufactured by a subsequent process.

Alternatively, add 200 ml of 99% ethanol to the CZTSe nanoink composition in 1 hour. Then, filter the CZTSe nanoink composition with a filter paper (whatman#2). Afterward, rinse the filtrate with 4000 ml of ethanol and 2000 ml of acetone. Finally, the filtrate undergoes a drying process in a vacuum baker at 60° C. for 10 hours, thereby yielding 880 grams of CZTSe nanopowder.

After the CZTSe nanopowder has been prepared, a CZTSe sputtering target is manufactured by performing a forming process, a sintering process, and a thermal compression process. Eventually, with the CZTSe sputtering target, a CZTSe thin-film is formed on a substrate by sputtering and then subjected to a sintering process at 500° C.-580° C. for 30-60 minutes, such that the CZTSe thin-film acquires a quaternary monophase structure, that is, Cu₂ZnSnSe₄.

### Experiment VI

Provide a 1000 ml glass reaction flask. Put a Teflon blender in the glass reaction flask. Introduce nitrogen gas into the glass reaction flask, and fill the glass reaction flask with the nitrogen gas for 30 minutes. Add 273 grams of polyetheramine (JEFFAMINE° D-400 Polyetheramine, Huntsman) liquid, 12 grams of a p-phenylenediamine powder, and 15 grams of a 3-dibenzoselenophen-4-yl-phenylamine powder to the glass reaction flask. Then, add 28 grams of a copper powder, 14.2 grams of a zinc powder, 26 grams of a tin powder, and 70 grams of a selenium powder, wherein each of which features a 99.99% purity. Perform blending for 5 hours to remove water vapor and oxygen gas from the mixture in the glass reaction flask. Heat the mixture in the glass reaction flask to 230-250° C. with a heater capable of controlling temperature, such that the chemical reaction occurs to the mixture under the aforesaid condition for 25 hours. Afterward, turn off the heater to allow the temperature to drop spontaneously to room temperature, which is about 30° C.

A black liquid thus manufactured is the anticipated CZTSe nanoink composition. The CZTSe nanoink composition can be directly applied to the substrate by a spray coating technique or a screen printing technique, and then the absorption layer of a thin-film solar cell is manufactured by a subsequent process.

Alternatively, add 200 ml of 99% ethanol to the CZTSe nanoink composition in 1 hour. Then, filter the CZTSe nanoink composition with a filter paper (whatman#2). Afterward, rinse the filtrate with 4000 ml of ethanol and 2000 ml of acetone. Finally, the filtrate undergoes a drying process in a vacuum baker at 60° C. for 10 hours, thereby yielding 138 grams of CZTSe nanopowder.

After the CZTSe nanopowder has been prepared, a CZTSe sputtering target is manufactured by performing a forming process, a sintering process, and a thermal compression process. Eventually, with the CZTSe sputtering target, a CZTSe thin-film is formed on a substrate by sputtering and then subjected to a sintering process at 500° C.-580° C. for 30-60 minutes, such that the CZTSe thin-film acquires a quaternary monophase structure, that is, Cu₂ZnSnSe₄.

In each of the examples, the reaction stops in the course of synthesis, such that the CZTSe nanoink composition, the CZTSe nanopowder, and the CZTSe sputtering target stop reacting before forming a quaternary monophase mixture, and in consequence they each comprise a binary multiphase mixture and/or a ternary multiphase mixture, or further comprise a single element such as Cu, Zn, Sn, or Se, but do not comprise a quaternary monophase mixture. Hence, when the CZTSe thin-film thus manufactured subsequently functions as an absorption layer of a thin-film solar cell, the absorption layer features a perfect quaternary monophase structure but does not manifest an intractable impure phase, thereby enhancing the photoelectric conversion efficiency of thin-film solar cells.

Furthermore, a chelating agent comprising p-phenylenediamine and 3-dibenzoselenophen-4-yl-phenylamine is employed with a view to shortening the required duration of reaction. Given appropriate equipment, such as the glass reaction flask, it is feasible to manufacture the CZTSe nanoink composition, the CZTSe nanopowder, and the CZTSe sputtering target by mass production, thereby cutting equipment costs and manufacturing costs greatly.

The foregoing embodiments are provided to illustrate the characteristics of the present invention so as to enable persons skilled in the art to understand the disclosure of the present invention and implement the present invention accordingly, and are not intended to be restrictive of the scope of the present invention. Hence, all equivalent modifications and changes made to the foregoing embodiments without departing from the spirit embodied in the disclosure of the present invention should fall within the scope of the present invention as set forth in the appended claims.

What is claimed is:

1. A Cu₂ZnSnSe₄ (CZTSe) nanoink composition for use in manufacturing an absorption layer of a thin-film solar cell, the CZTSe nanoink composition comprising:
a chelating agent comprising a polyetheramine selected from the group consisting of a monoamine, a diamine, and a triamine; and
a binary multiphase mixture formed by combining any two elements of copper, zinc, tin, and selenium via the chelating agent.

2. The CZTSe nanoink composition of claim 1, further comprising a ternary multiphase mixture formed by combining any three elements of the copper, the zinc, the tin, and the selenium via the chelating agent.

3. The CZTSe nanoink composition of claim 1, further comprising a single element, the single element being the copper, the zinc, the tin, or the selenium.

4. The CZTSe nanoink composition of claim 2, further comprising a single element, the single element being the copper, the zinc, the tin, or the selenium.

5. The CZTSe nanoink composition of claim 1, wherein the chelating agent further comprises p-phenylenediamine and 3-dibenzoselenophen-4-yl-phenylamine.

6. The CZTSe nanoink composition of claim 1, wherein the monoamine is selected from the group consisting of alkyl polyalkylene glycol amine, bis(methyl triethylene glycol) amine, butyl triethylene glycol amine, lauryl polypropylene glycol amine, methyl tripropylene glycol amine, phenol polypropylene glycol amine, polypropylene glycol amine, bis(methyl tripropylene glycol) amine, N-methyl methyl propylene glycol amine, methyl polypropylene glycol amine, bis(methyl polypropylene glycol) amine, tris(methyl diglycol) amine, methyl polyalkylene glycol amine with random or blockwise distribution of the ethylene glycol, and propylene glycol.

7. The CZTSe nanoink composition of claim 1, wherein the diamine is selected from the group consisting of triethylene glycol diamine, tripropylene glycol diamine, polyethylene glycol diamine, polypropylene glycol diamine, polyalkylene glycol diamine with random or blockwise distribution of ethylene glycol and propylene glycol units, butanediol polyalkylene glycol diamine, and resorcinol polyalkylene glycol diamine.

8. The CZTSe nanoink composition of claim 1, wherein the triamine is selected from the group consisting of glycerol polyalkylene glycol triamine with random or blockwise distribution of the ethylene glycol and propylene glycol unit, bis(triethylene glycol amine) amine, and bis(polyalkylene glycol amine) amine.

9. A Cu₂ZnSnSe₄ (CZTSe) nanoink composition for use in manufacturing an absorption layer of a thin-film solar cell, the CZTSe nanoink composition comprising:
a chelating agent comprising a polyetheramine selected from the group consisting of a monoamine, a diamine, and a triamine; and
a ternary multiphase mixture of any three elements selected from the group consisting of copper, zinc, tin, and selenium and combined via the chelating agent.

10. The CZTSe nanoink composition of claim 9, further comprising a single element, the single element being the copper, the zinc, the tin, or the selenium.

11. The CZTSe nanoink composition of claim 9, wherein the chelating agent further comprises p-phenylenediamine and 3-dibenzoselenophen-4-yl-phenylamine.

12. The CZTSe nanoink composition of claim 9, wherein the monoamine is selected from the group consisting of alkyl polyalkylene glycol amine, bis(methyl triethylene glycol) amine, butyl triethylene glycol amine, lauryl polypropylene glycol amine, methyl tripropylene glycol amine, phenol polypropylene glycol amine, polypropylene glycol amine, bis(methyl tripropylene glycol) amine, N-methyl methyl propylene glycol amine, methyl polypropylene glycol amine, bis(methyl polypropylene glycol) amine, tris(methyl diglycol) amine, methyl polyalkylene glycol amine with random or blockwise distribution of the ethylene glycol, and propylene glycol.

13. The CZTSe nanoink composition of claim 9, wherein the diamine is selected from the group consisting of triethylene glycol diamine, tripropylene glycol diamine, polyethylene glycol diamine, polypropylene glycol diamine, polyalkylene glycol diamine with random or blockwise distribution of ethylene glycol and propylene glycol units, butanediol polyalkylene glycol diamine, and resorcinol polyalkylene glycol diamine.

14. The CZTSe nanoink composition of claim 9, wherein the triamine is selected from the group consisting of glycerol polyalkylene glycol triamine with random or blockwise distribution of the ethylene glycol and propylene glycol unit, bis(triethylene glycol amine) amine, and bis(polyalkylene glycol amine) amine.

15. A Cu₂ZnSnSe₄ (CZTSe) sputtering target for use in manufacturing an absorption layer of a thin-film solar cell, the CZTSe sputtering target comprising a binary multiphase mixture of any two elements selected from the group consisting of copper, zinc, tin, and selenium.

16. The CZTSe sputtering target of claim 15, further comprising a ternary multiphase mixture of any three elements selected from the group consisting of the copper, the zinc, the tin, and the selenium.

17. The CZTSe sputtering target of claim 15, further comprising a single element, the single element being the copper, the zinc, the tin, or the selenium.

18. The CZTSe sputtering target of claim 16, further comprising a single element, the single element being the copper, the zinc, the tin, or the selenium.

19. A Cu₂ZnSnSe₄ (CZTSe) sputtering target for use in manufacturing an absorption layer of a thin-film solar cell, the CZTSe sputtering target comprising a ternary multiphase mixture of any three elements selected from the group consisting of copper, zinc, tin, and selenium.

20. The CZTSe sputtering target of claim 19, further comprising a single element, the single element being the copper, the zinc, the tin, or the selenium.
